(19) United States
(12) Patent Application Publication
(10) Pub. No.: US 2011/0284054 A1
(43) Pub. Date: Nov. 24, 2011

(54) SPECTRAL SPLITTING FOR MULTI-BANDGAP PHOTOVOLTAIC ENERGY CONVERSION

(75) Inventor: Mark W. Wanlass, Evergreen, CO (US)

(73) Assignee: ALLIANCE FOR SUSTAINABLE ENERGY, LLC, GOLDEN, CO (US)

(21) Appl. No.: 13/146,381

(22) PCT Filed: Jan. 28, 2009
(86) PCT No.: PCT/US09/32290

§ 371 Date: Jul. 26, 2011

(51) Int. Cl. H01L 31/052

(52) U.S. Cl. 136/246

(57) ABSTRACT

A spectrum-splitting photovoltaic converter system (10) includes a high energy cell (20) and a low energy cell (30) positioned in adjacent, non-coplanar relation to each other, wherein the high energy cell (20) is the spectral splitting optical component and utilizes a combination of a dual purpose optical coating (40) comprising an anti-reflection coating, a highly reflective back surface reflector (42), and a dielectric spacer (44) to maximize transmittance of high energy into the high energy cell (20) for conversion to electric energy and to maximize reflection of low energy from the high energy cell (20) to the low energy cell (30) for conversion to electrical energy.

### CONTRACTUAL ORIGIN

The United States Government has rights in this invention under Contract No. DE-AC36-08GO23308 between the United States Department of Energy and the Alliance for Sustainable Energy, LLC, the manager and operator of the National Renewable Energy Laboratory.

### BACKGROUND

Multiple bandgap photovoltaic energy converters are used to convert solar energy to electricity in situations where higher conversion efficiencies are needed, because the solar spectrum includes a broad range of electromagnetic energy bands, and multiple bandgap converter cells or subcells can convert more of the energy in the spectrum to electricity than single bandgap devices. Therefore, more efficient broadband solar energy converters typically include two, three, or more subcells with different bandgaps. In some converters the subcells are grown together in a monolithic structure, but in others they are grown separately and assembled together in a stack. However, such multi-bandgap solar cell schemes, where the whole broadband solar spectrum is directed onto one cell for propagation into the subcells, have some inherent problems and limitations. For example, at any surface or interface, some light will be reflected. To minimize such reflection, it is common to deposit an anti-reflection coating (ARC) on the front face or surface of photovoltaic converters. However, broadband anti-reflection coatings with good light transmission efficiencies over the entire broadband spectrum are difficult to make. Also, converter devices with multiple bandgaps are difficult and expensive to make.

Another approach that has been tried is to split the broadband solar spectrum into two or more narrower energy bands and direct the individual narrower energy bands to separate photovoltaic cells with different bandgaps. Each cell has a bandgap tailored to a solar energy band that is directed to it in order to optimize energy conversion. Such spectral splitting of the broadband solar energy has been done with prisms, dichroic mirrors, dichroic filters, and other color-selective optical components. Advantages of such spectral splitting schemes include having to deal only with narrower band anti-reflection coatings and narrower families of subcells; but disadvantages include more complexity with more parts, and more interfaces generally result in more energy losses.

In his International (Patent Cooperation Treaty) Patent Application No. WO 87/01512, published 12 Mar. 1987, Ellion discusses all of those schemes mentioned above as well as the concept of a plurality of serially non-coplanar solar cells in which a higher bandgap photovoltaic cell intercepts and absorbs higher energy band light first, while mid-range and lower energy bands pass through the higher bandgap cell to get to the lower bandgap cells. In some of Ellion's arrangements, the lower energy light passes straight through the higher bandgap cells, while in others, silvered back surfaces reflect the unabsorbed light back through the cell to the front, from where it is directed to a subsequent cell with a lower bandgap. While the plurality of serially non-coplanar cells proposed by Ellion may integrate the solar cells into the spectral splitting function, the components and structures as described still suffer from too many losses, thus are not practical or cost-effective.

The foregoing examples of related art and limitations related therewith are intended to be illustrative and not exclusive. Other limitations of the related art will become apparent to those skilled in the art upon a reading of the specification and a study of the drawings.

### SUMMARY

The following embodiments and aspects thereof are described and illustrated in conjunction with systems, tools and methods which are meant to be exemplary and illustrative, not limiting in scope. In various embodiments, one or more of the above-described problems have been reduced or eliminated, while other embodiments are directed to other improvements.

Implementations of a split-spectrum photovoltaic converter achieve ultra-high energy conversion efficiency when using spectral splitting in photovoltaic conversion systems that are illuminated by broad radiation energy bands, including, but not limited to, solar radiation. Improved serially non-coplanar photovoltaic cell assemblies reduce losses and thereby make such assemblies more efficient and effective for use in spectral splitting photovoltaic converter applications, and they make photovoltaic converter systems based on spectral splitting more practical and viable.

In addition to the exemplary aspects and embodiments described above, further aspects and embodiments will become apparent by reference to the drawings and by study of the following descriptions.

### BRIEF DESCRIPTION OF THE DRAWINGS

The accompanying drawings, which are incorporated herein and form a part of the specification, illustrate some, but not the only or exclusive, example embodiments and/or features. It is intended that the embodiments and figures disclosed herein are to be considered illustrative rather than limiting.

FIG. 1 is a cross-sectional diagrammatic view of an example split, multi-bandgap photovoltaic converter assembly;

FIG. 2 is a reflectance model for an anti-reflection coating, back surface reflector, and dielectric spacer in various combinations with two example subcells;

FIGS. 3a-d illustrate diagrammatically the stages in fabrication of an ultra-thin cell;

FIG. 4 is a reflectance model of an anti-reflection coating, dielectric spacer, and back surface reflector on a semiconductor device with different angles of incidence of the light;

FIG. 5 is a side elevation view of another implementation of split-spectrum, non-coplanar converter assembly;

FIG. 6 is a side elevation view of an expanded layout of high energy and low energy cells in a split-spectrum converter assembly; and

FIG. 7 is a side elevation view of still another implementation of split-spectrum, non-coplanar cells, including the option of a third cell.

### DETAILED DESCRIPTION OF EXAMPLE EMBODIMENTS

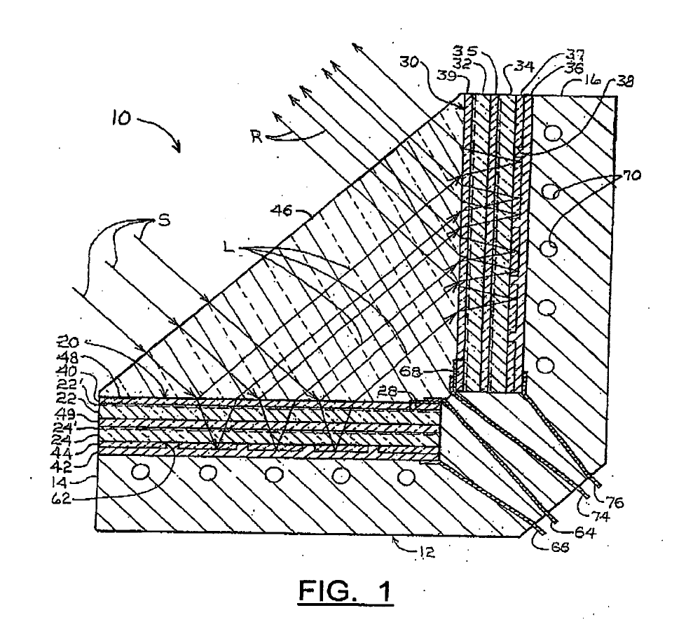

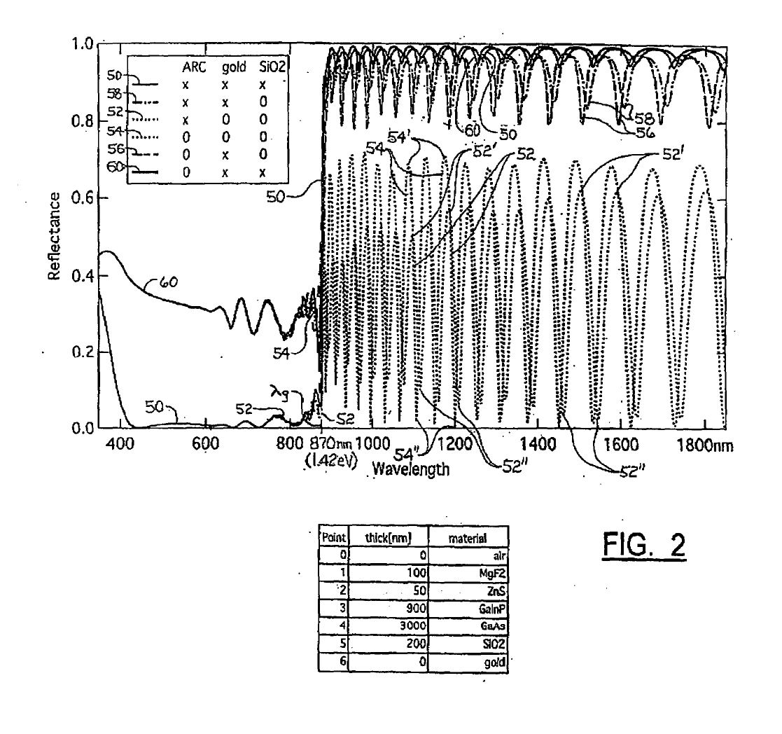

For an overview of several features and principles, an example split-spectrum, multi-bandgap, photovoltaic converter assembly 10 is shown in FIG. 1 with an ultra-thin, inverted, multi-bandgap, monolithic, high energy, photovoltaic converter 20 mounted on the first platform 14 of a support structure or receiver 12, and an ultra-thin, inverted, multi-bandgap, monolithic, low-energy, photovoltaic converter 30 mounted on a non-coplanar second platform 16 of the receiver 12. In this example, split-spectrum converter assembly 10, shown in FIG. 1, the high E converter or cell 20 is shown with two example subcells 22, 24 with bandgaps designed to absorb and convert a higher energy band of light (i.e., shorter wavelength band) in the solar spectrum to electric energy. A dual purpose optical coating (DPOC) 40 on the front surface of the high E cell 20, augmented by a back surface reflector (BSR) 42 and dielectric spacer 44, is engineered to have characteristics coordinated with the bandgaps of the subcells 22, 24 to ensure that as much of the higher energy band of the incident solar radiation S as possible is transmitted into, absorbed, and converted to electricity by the high E cell 20 and that as much of the lower energy band light L of the incident solar radiation S as possible is reflected to the low E converter or cell 30. To achieve that goal, the lowest bandgap subcell 24 sets the lower edge of a high energy band of light at a boundary or cut-off wavelength λ_{g}, as illustrated in FIG. 2, which is the longest wavelength that is convertible to electric energy by the lowest bandgap cell 24, the dual purpose optical coating 40 comprises a narrow band anti-reflection coating (ARC) with a very low reflectance, thus a very high transmittance, for light within the high energy band. The high energy band extends from the boundary or cut-off wavelength λ_{g} at least to an energy level that is higher than the longest wavelength of light that is absorbable and convertible to electric energy by the highest bandgap subcell 22 in the high E cell 20. It can extend to the highest wavelength in the incident solar spectrum. Since anti-reflection coatings are tuned to wavelengths by index of diffraction and thickness of the dielectric materials used as layers in the anti-reflection coatings, it is difficult to provide an anti-reflection coating that has very low reflectance and very high transmittance for all wavelengths shorter than the cut-off wavelength λ_{g}, as indicated by the sharp rise in trace 50 in FIG. 2 in the very short wavelengths around about 400 nm. At some point, designing an anti-reflection coating for broader band coverage compromises the low reflectance that is possible and feasible for a narrower band. Therefore, broadening the anti-reflection coating band to a point where photocurrent cannot be maximized and the quantum efficiency decreases may be counter-productive and can provide a practical limit on the high energy band for which the anti-reflection coating of the DPOC 40 is engineered.

A very significant proportion of the lower energy light L, i.e., wavelengths longer than the cut-off energy λ_{g}, is reflected by the dual purpose optical coating 40 to the low E cell 30 for absorption and conversion to electricity. The back surface reflector 42 on the high E cell 20, augmented by the dielectric spacer 44, reflects almost all of any remaining lower energy radiation L, which is not reflected by the dual purpose optical coating 40, back through the high E cell 20 to the low E cell 30, as will be explained in more detail below. A total internal reflection (TIR) optical element 46 positioned between the high E cell 20 and the low E cell 30 captures stray or diffusely reflected rays from the top surface 48 of the high E cell 20 and directs them to the low E cell 30.

As mentioned above, the split-spectrum photovoltaic converter assembly 10 is shown as one example, but not the only, implementation that demonstrates a number of features and principles used to achieve higher light energy to electric energy conversion efficiencies in serially non-coplanar photovoltaic cell assemblies. Therefore, this description will proceed with reference to the example shown in FIG. 1, but with the understanding that the claims below can also be implemented in myriad other ways once the principles are understood from the descriptions and explanations herein, and that some, but not all, of such other implementations and enhancements are also described or mentioned below.

The cross-sectional view of the example split-spectrum converter assembly 10 in FIG. 1 is diagrammatic, and various component sizes and proportions are exaggerated or not true to scale because of the impracticality of illustrating micron-sized thin-film layer thickness and other components in semiconductor device structures in true scale or proportionate sizes, as is understood by persons skilled in the art. Other examples and illustrations in other figures of the accompanying drawings are also not drawn in true sizes and proportions, but persons skilled in the art can understand them.

While not essential, multiple bandgaps in the high E cell 20 and multiple bandgaps in the low E cell 30 can provide higher energy conversion efficiencies than single bandgap high E and/or low E cells. A certain amount of photon energy is required to excite electrons enough to jump the bandgap of a semiconductor material. Any incident photon energy in excess of that amount is thermalized and wasted as heat, and any incident photon energy that is insufficient to cause an electron to jump the bandgap is not able to convert to electric energy in that cell. Therefore, multiple different bandgaps provide more efficient conversion of light in multiple different wavelength bands to electricity, thus reducing energy loss to transmission and heat. Consequently, as a general rule, the overall light energy to electric energy conversion efficiency for the solar spectrum is higher with multiple cells or subcells having different bandgaps distributed throughout the energy bands or spectrum of the incident light than with a single cell having a single bandgap. Such multiple different bandgaps can be provided by numerous single bandgap cells arranged in series, as shown by Ellion in the International Patent Application no. WO 87/01512. However, that approach is inadequate for efficient, high performance, photovoltaic energy conversion. Mounting numerous cells adds complexity and cost, each reflection has an associated energy loss, and there are refractive energy losses at the numerous surfaces.

Consequently, the dilemma has been that, on the one hand, the use of one multi-bandgap cell with no optical splitting of the broad solar spectrum suffers from the inability of anti-reflection coatings to provide uniformly low reflectance, i.e., high transmittance, for all of the incident light over the entire spectrum, while, on the other hand, too many spectral splits by too many individual cells or other optical components presents too many surfaces, interfaces, and other loss mechanisms, which is counter-productive to achieving high conversion efficiency, high performance, and low cost. However, simply balancing the two approaches by finding some happy medium between them, such as by reducing the number of cells and providing multiple subcells in each cell, while beneficial, is not in itself enough to solve the problem of making split spectrum converters attractive commercially, because the loss problems associated with even as few as two conventional cells in a split spectrum arrangement out-weigh the marginal benefits to be had by splitting of the broad spectrum of light into two energy bands for conversion separately by the two cells. To make split-spectrum solar cell assemblies efficient enough to be commercially viable, comprehensive optical management and loss reduction is required, as described below.

In the example split-spectrum converter assembly 10 shown in FIG. 1, two non-coplanar, ultra-thin, multi-bandgap cells are illustrated, i.e., the high E cell 20 and the low E cell 30. The high E cell 20 is illustrated in FIG. 1 with two subcells 22, 24 with different bandgaps, and the low E cell 30 is illustrated in FIG. 1 with two subcells 32, 34 with different bandgaps, as will be described in more detail below. However, more than two subcells with different bandgaps can be used in either or both of the two cells 20, 30. Also, it may be feasible for some applications to include two or more subcells with different bandgaps in the high E cell and only one bandgap in the low E cell. For example, a single, relatively inexpensive CuInSe₂ low E cell 30 with a bandgap of about 0.69 eV may be feasible in situations where minimization of cost outweighs ultimate performance needs.

As mentioned above, the example high E cell 20 has a narrow band, dual purpose optical coating 40 at its front end and a back surface reflector 42 at its back end. In general, when discussing orientations of photovoltaic converters, it is understood that the incident light enters a cell at its front end and propagates through the cell toward its back end if not reflected or absorbed, and that conventional terminology is used here. The incident light, e.g., solar radiation S, is transmitted by the TIR optical element 46 to the high E cell 20, where it is incident on the front surface 48. The dual purpose optical coating (DPOC) 40 comprises a narrow band anti-reflection coating (ARC) that transmits light in the wavelength band that the high E cell 20 is designed to absorb and convert to electric energy, e.g., the shorter wavelength, higher energy radiation in the incident solar light S, and it, in a complex optical interaction with the back surface reflector 42, dielectric spacer 44, and subcells 22, 24, reflects the longer wavelength, lower energy light L in the incident solar light S, i.e., wavelengths longer than can be absorbed and converted to electric energy by the lowest bandgap subcell 24 in the high E cell 20, as illustrated in FIG. 2. The reflected, lower energy light L is transmitted by the TIR optical element 46 to the low E cell 30, where it is absorbed and converted to electric energy, as will be discussed below. As mentioned above, the back surface reflector (BSR) 42 on the back end of the high E cell 20 reflects any low energy light L that gets through the dual purpose optical coating 40 and into the high E cell so that it then gets transmitted by the TIR optical element 46 to the low E cell 30. While only one reflection of the unabsorbed, low energy light L off the BSR 42 is illustrated in FIG. 1 to keep the drawing from becoming too cluttered, some of the low energy light L in the high E cell 20 actually gets reflected back and forth between the BSR 42 and the DPOC 40 more than once, probably numerous times, before emerging from the high E cell 20 for transmission by the TIR optical element 46 to the low E cell 30. Any place there is a surface or interface between different materials, there is reflection. Therefore, while the high energy light gets transmitted by the dual purpose optical coating 40 into the high E cell 20, where it is promptly absorbed and converted to electric energy by the subcells 22, 24, the low energy light that gets transmitted into the high E cell 20 immediately gets reflected many, many times at numerous surfaces and interfaces, thereby causing constructive and destructive optical interferences and, wherever there are free carriers, absorptions. Consequently, the use of an ultra-thin high E cell 20, i.e., one that no longer has its parent substrate on which it was grown, minimizes free carrier absorption of the low energy light traversing the high E cell 20 between the DPOC 40 and the BSR 42 that may otherwise occur in a conventional cell that still has its parent substrate, thereby minimizing one of the loss causalities that have made it impractical to use the wavelength selectivity of a cell for the spectrum splitting function in split spectrum energy converter systems.

As mentioned above, the dual purpose optical coating (DPOC) 40 is designed to be very transmissive within the high energy band. For example, the high E cell 20 illustrated in FIG. 1 comprises two subcells 22, 24, as mentioned above. The first or front subcell 22 in this example may be GaInP with a bandgap of about 1.85 eV and doped to have a n/p or a p/n junction 22′, and the second or back subcell 24 may be GaAs with a bandgap of 1.42 eV and doped to have a n/p or p/n junction 24′. Therefore, in this example, the front subcell 22 with its bandgap of 1.85 eV will absorb and convert to electricity the light that has wavelengths of about 670 nm and shorter, but will transmit light with wavelengths longer than 670 nm. The back subcell 24 with its bandgap of 1.42 eV will absorb and convert to electricity the light transmitted by the subcell 22 that has wavelengths of about 870 nm and shorter, which is where the reflectance goes abruptly from very low to very high and defines the boundary or cut-off wavelength λ_{g}, as shown in FIG. 2, i.e., which is where the high E cell 20 becomes transparent to longer wavelengths. In other words, the high E cell 20 will not absorb and convert light with wavelengths longer than λ_{g}, which is about 870 nm in this example. Instead, the back subcell 24 is transparent to light with wavelengths longer than 870 nm and will transmit it. As a result, any light with wavelengths longer than about 870 nm cannot be converted to electricity by this example high E cell 20, and such low energy light L is wasted if not for the low E cell 30.

For wavelengths to which the high E cell 20 is transparent, i.e., longer than λ_{g} as explained above, the dual purpose optical coating 40 is at least somewhat reflective, as will be explained below, and it will reflect a substantial proportion of the lower energy light L, i.e., wavelengths longer than λ_{g}, to the low E cell 30 before such low energy light L gets into the high E cell 20. One benefit of this design is that none of the low energy light L reflected by the dual purpose optical coating 40 to the low E cell 30 will be exposed to the loss causalities in the high E cell 20, which marginally increases conversion efficiency and performance of the entire split-spectrum converter assembly 10 over what it would be if all of the low energy light L was allowed or made to enter the high E cell 20 before being transmitted to the low E cell 30.

The reflectance characteristics of an example MgF₂/ZnS anti-reflection coating ARC modeled for use as the dual purpose optical coating (DPOC) 40 on the high E cell 20 example described above, including a metal (gold) back surface reflector (BSR) 42 and a SiO₂ dielectric spacer 44 (explained in more detail below), are shown in FIG. 2. In FIG. 2, the trace 50 represents the reflectance of the modeled high E cell 20, including the dual purpose optical coating 40, the gold back surface reflector (BSR) 42, and the dielectric spacer 44. It shows the modeled results for an anti-reflection coating (ARC) comprising 100 nm MgF₂ and 50 nm ZnS to function as the dual purpose optical coating 40, on a 900 nm thick GaInP front subcell 20, 3,000 nm thick GaAs back cell 30, 200 nm thick SiO₂ dielectric spacer layer 44, and a gold back surface reflector (BSR) 42. This model in FIG. 2 is not a perfect model, so it is not entirely accurate, but it is instructive and useful. For example, the subcells are modeled without dopants, thus are presented as pure dielectrics with no free carriers that can absorb light energy, albeit, not convert it to electric energy if the wavelengths are longer than the cut-off wavelength λ_{g}. Therefore, there would actually be some more absorption, thus slightly less reflectance in an actual cell as compared to the modeled cell in FIG. 2, but the difference would not be great.

As can be seen from that trace 50, the total reflectance of that combination of materials is near zero in the high energy band extending from about 400 nm wavelength to the transition or boundary wavelength λ_{g} of about 870 nm wavelength, which includes practically all of the visible portion of the solar spectrum (about 400 nm to 700 nm) and extends into the near infrared portion of the spectrum. At the boundary or cut-off wavelength λ_{g} of about 870 nm, which, as explained above, is the longest wavelength light that can be absorbed and converted to electrical energy by the back subcell 24 in the high E cell 20 with its 1.42 eV bandgap, the reflectance represented by trace 50 increases abruptly to very close to unity, i.e., 100 percent, reflectance of the lower energy, infrared, portion of the solar spectrum with wavelengths longer than 870 nm and extending at least to 1,850 nm and beyond. Consequently, as shown by the trace 50, almost all of the high energy light in the solar spectrum with wavelengths shorter than 870 nm in this example is transmitted into the high E cell 20, where it is absorbed immediately and converted to electric energy by the subcells 22, 24, thus cannot contribute to any reflectance, whereas almost all of the low energy light L with wavelengths longer than 870 nm is reflected to the low E cell 30.

It is also instructive to see that the anti-reflection coating 40 by itself on the high E cell 20, represented by the trace 52 in FIG. 2 (i.e., with no back surface reflector 42 or dielectric spacer 44), is virtually congruent with the trace 50 in wavelengths shorter than 870 nm, whereas the reflectance of the subcells 22, 24 alone, represented by the trace 54 (i.e., without the anti-reflection coating 40, back surface reflector 42, or dielectric spacer 44), is substantially higher than the reflectance of the high E cell 20 with the anti-reflection coating 40. This distinction indicates that the anti-reflection coating used for the dual purpose optical coating 40, which is designed and modeled with the subcells 22, 24 for maximizing transmittance and minimizing reflectance of those shorter wavelengths into the high E cell 20, is primarily responsible for the almost unity, i.e., 100 percent, transmission of incident light wavelengths shorter than about 870 nm into the high E cell 20.

However, in wavelengths longer than 870 nm, the reflectance of the anti-reflection coating 40 alone on the high E cell 20 (i.e., without the BSR 42 and dielectric spacer 44), represented by the trace 52, increases substantially, which shows that it does reflect a significant proportion, approximately 30 to 40 percent on average in this example, of the light L that is longer wavelength than 870 nm. This amount of the longer wavelength light reflected at the surface 48 by the dual purpose optical coating 40 is significant because that reflected light never gets into or is exposed to the loss causalities in the high E cell 20, which include, but are not limited to, an abundance of free charge carriers (electrons and holes) in the subcells 22, 24, that may cause a certain amount of low energy absorption. Such absorption of light that is lower energy than the bandgap of the semiconductor material may cause that energy to be thermalized to heat. Therefore, the reflectance of at least some of the longer wavelength light L by the dual purpose optical coating 40 to the low E cell 30 avoids at least some of that energy from being absorbed in the high E cell 20 and dissipated as heat, thus reducing losses and adding a marginal increase in energy conversion efficiency that contributes along with other improvements to the overall efficiency and performance of the split spectrum converter assembly 10.

The oscillations in the trace 52 between maxima 52′ and minima 52″ in the longer wavelength light in FIG. 2, which begin immediately at the cut-off wavelength λ_{g}, are due to Fabry-Perot constructive and destructive interferences between the incident light that is not absorbed in the high E cell 20 and multiple reflections from the surfaces of the cell and interfaces with the subcells, which are damped to some extent by the ARC (serving as the dual purpose optical coating 40) as compared to the maxima 54′ and minima 54″ of the trace 54 that represents the high E cell 20 with no ARC or dual purpose optical coating. The trace 52 in FIG. 2 indicates that approximately 30 to 40 percent of the longer than 870 nm light is reflected by the ARC used as the dual purpose optical coating 40 in that example, which can be varied by ARC layer materials, thicknesses, and other design parameters. ARC modeling programs, for example, TF Calc™ available from Software Spectra, Inc., in Portland, Oreg., USA, or Film Wizard™ available from Scientific Computing International in Carlsbad, Calif., USA, can be used by persons skilled in the art to design dual purpose optical coatings for specific cell designs for split-spectrum photovoltaic converters, once they understand that the goal is to maximize transmission of higher energy light and to maximize reflection of lower energy light, but with the emphasis on maximizing transmittance of the high energy light, because the BSR 42 and dielectric spacer 44 in combination with the DPOC 40 effectively maximize reflectance of the low energy light L.

As mentioned above, at least some of any lower energy light L transmitted into the high E cell 20 will be thermalized and lost as dissipated heat due to absorption by free charge carriers (e.g., electrons and holes) in the semiconductor materials (sometimes called simply “free carriers”). Also, at least some of any high energy light (wavelengths shorter than λ_{g}) that gets reflected into the low E cell 30 will be thermalized and lost as dissipated heat due to excess photon energy over the highest bandgap energy E_{g} in the low E cell 30. Therefore, these losses can be minimized by providing a dual purpose optical coating 40 on the front of the high E cell 20 that transmits as much of the incident high energy light as possible into the high E cell 20 and, as complemented and enhanced by the BSR 42 and dielectric spacer 44, reflects as much of the low energy light as possible to the low E cell 30

It should be noted that the example ARC model in FIG. 2 assumes the high E cell 20 in ambient atmosphere without the TIR optical element 46 in place. A more accurate model would also take into consideration the index of refraction of the TIR optical element 46 instead of air, and the actual reflectance of low energy light L by the dual purpose optical coating 40 may be even better with the TIR optical element 46 in place than is indicated by the model in FIG. 2.

As mentioned above, the low energy light L reflectance by the dual purpose optical coating 40 is augmented by the back surface reflector (BSR) 42 and dielectric spacer 44 illustrated in FIG. 1. Practically all of the high energy light (i.e., wavelength shorter than the cut-off wavelength λ_{g}) in the solar radiation S that is not reflected by the dual purpose optical coating 40 gets transmitted into the high E cell 20, as shown by the trace 52 in FIG. 2 and discussed above, and some of the low energy light L does not get reflected, thus also enters the high E cell 20. The low energy light L that does get into the high E cell 20 and does not get absorbed by free charge carriers in the semiconductor material in the high E cell 20, is transmitted by the subcells 22, 24 to the back surface reflector (BSR) 42, where it gets reflected by the back surface reflector 42 augmented by the dielectric spacer 44, as will be explained in more detail below.

As mentioned above, absorption of the low energy light (wavelengths longer than the cut-off wavelength λ_{g}) is minimized or reduced further in the high E cell 20 by having the doped parent substrate on which the subcells are grown removed, which makes it an ultra-thin cell. Such monolithic, multi-bandgap, tandem, photovoltaic cells that have their parent substrates removed after mounting the cells on foreign handles or secondary carriers, which may be a component of the receiver 12 in this case, are known as ultra-thin, monolithic, multi-bandgap, tandem photovoltaic cells, or just ultra-thin cells for convenience. The removal of the parent substrate eliminates a relatively thick mass of semiconductor material with free carriers from the cell structure, which would otherwise be a significant absorber of the low energy light L that propagates into the high E cell 20. Some absorption of the low energy light can still occur in the subcells 22, 24, tunnel junction 49, and any other semiconductor layers in the remaining ultra-thin, high E cell 20, but elimination of the parent substrate prevents a significant amount of low energy light absorption, thereby reducing additional marginal losses of light energy in the high E cell 20, and the entire high E cell 20 is almost totally transparent to the wavelengths longer than the cut-off wavelength λ_{g}. so, with very little absorption loss, the reflectance of the high E cell 20 is near 100 percent for wavelengths longer than the cut-off wavelength λ_{g}. Therefore, while use of an ultra-thin cell structure for the high E cell 20 is not essential, it will contribute to the overall light conversion to electricity performance and efficiency of the split-spectrum photovoltaic converter 10.

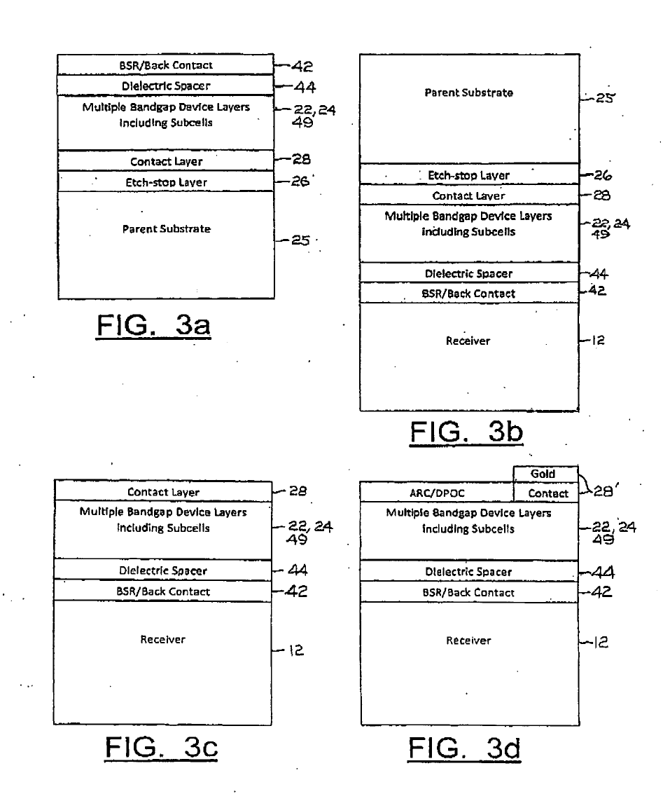

Persons skilled in the art are capable of making ultra-thin cells, as explained, for example, in U.S. patent application Ser. No. 11/027,156, published on Jul. 6, 2006 (Publication No. 2006/0144435 A1), which is incorporated herein by reference. Therefore, it is not necessary to describe in detail herein how to make an ultra-thin cells for use as the high E cell 20 in the split-spectrum photovoltaic converter assembly 10. Suffice it to say that the high E cell 20 is grown epitaxially on a crystalline parent substrate 25, as illustrated diagrammatically in FIG. 3a, including an etch-stop layer 26 between the substrate 25 and device layers comprising the subcells 22, 24 and tunnel junction 49. While not essential, it is beneficial to grow the subcells 22, 24 in inverse order, i.e., growing the highest bandgap subcell 22 on the substrate 25 first before the lower bandgap subcell(s) 24. For example, such an inverted cell structure facilitates depositing dielectric spacer 44 and back surface reflector 42 on the lower bandgap subcell 30 of the high E cell 10 before it is mounted on a handle, e.g., on a receiver component 12, and before the parent substrate 20 is removed, as illustrated diagrammatically in FIGS. 3a, 3b, and 3c. The back surface reflector 42 can be a highly conductive metal, e.g., gold, so that it can also function as the back contact and can be mounted directly on the handle or receiver 12, as illustrated diagrammatically in FIG. 3b; perforations 62 in the dielectric spacer can be formed to facilitate electric contact and conductivity. The device layers 22, 24, 49, dielectric spacer 44, and BSR/back contact 42 may also be mounted on a separate handle (not shown) which may then be mounted on the receiver 12 if desired. The etch-stop layer 26 protects the device layers as the substrate 25 is removed by etching it away, after which the etch-stop layer 26 is also etched away to expose the front contact layer 28, as illustrated diagrammatically in FIG. 3c. Finally, a metal grid (e.g., gold) is electroplated, deposited, or otherwise placed on the front contact layer 28, and part of the front contact layer 28 between the grids is etched away to leave a contact grid 28′, and the ARC/dual purpose optical coating 40 is added to complete the high E cell 20. Of course, other layers, such as passivation/carrier-confinement materials to form double heterostructures (DH) for the subcells, front and back electrically conductive contact layers, buffers, isolation layers and intermediate contacts for parallel subcell connection instead of series connection, and other components for monolithic, multi-bandgap, tandem, photovoltaic converter devices, which are not shown, can also be included in the structure of the high E cell 20, as would be understood by persons skilled in the art.

The gold back surface reflector (BSR) 42 is, of course, highly reflective of all light in the solar spectrum S, and, as illustrated by the trace 56 in FIG. 2, the gold back surface reflector (BSR) 42 by itself, i.e., without the ARC 40 and the dielectric spacer 44, is highly reflective of the light in the low energy range, i.e., wavelengths longer than the cut-off wavelength λ_{g}. Gold is the best metal for the BSR 42 over other metal reflectors because it is the most reflective metal in infrared light wavelengths. However, the oscillations in the trace 56 indicate constructive and destructive interference effects in the overall high E cell 20 structure, which occur because the overall cell structure is transparent to those longer wavelengths, and in conjunction with the BSR 42, cause it to behave like a Fabry-Perot cavity with many, many reflections within the cell structure. These many, many reflections and interference effects cause additional opportunities for light absorption by free carriers in the subcells, thus additional losses in the low energy light range. Also, as mentioned above, the model in FIG. 2 was done with no allowance for dopants, thus no free carriers, in the subcells that would in reality cause some absorption of energy. Also, for the gold back surface reflector 42, a textbook conductivity was used, which is finite, not infinite. Therefore, there is an abundance of free carriers in the gold, and multiple reflections within the cell structure to the gold, if the light is not coupled out of the cell structure, will cause absorption of energy in the gold. Therefore, in the FIG. 2 model, the only loss is in the gold BSR 42, not in the subcells. The dips in the reflectance curves are due to multiple reflections within the cell structure and the resulting constructive and destructive optical interference effects. However, as shown by the trace 58 in FIG. 2, the combination of the dual purpose optical coating 40 (ARC) with the BSR 42 has some reducing effect on the magnitude of the interference oscillations and results in a modest increase in reflectance, e.g., from about 80 percent to about 85 percent reflectance of the low energy light.

Further, however, the addition of the SiO₂ dielectric spacer 44 between subcell 24 and the back surface reflector (BSR) 42 jumps the reflectance up dramatically to about 95 percent with significantly reduced interference effect oscillation magnitudes, as shown by the trace 60 in FIG. 2. With the thickness of the dielectric spacer 44 optimized, it helps the dual purpose optical coating 40 to couple the low energy light back out of the high E cell 20 structure, which reduces light energy loss in the gold BSR 42. The optimal thickness of the dielectric spacer 44 may be different, depending on the cell design and dielectric material used, although typical dielectric material, e.g., SiO₂, MgF₂, etc., do not have a large impact on optimum thickness. For example, the thickness may be different for thicker or thinner subcells, and the lowest bandgap determines the wavelengths that will be reflected by the BSR 42, which affects the Fabry-Perot cavity interferences. However, the thickness of the dielectric spacer 44 that will be needed to maximize reflectance can be modeled to provide the best enhancement to the overall reflectance of the BSR 42 and dual purpose optical coating 40 on a particular cell 20.

There are essentially no free carriers in the dielectric material 44, so it does not add any absorption losses. The combination of the dual purpose optical coating 40 (ARC), gold BSR 42, and SiO₂ dielectric spacer 44 together reduce the magnitude of the interference oscillations even further and boost the overall reflectance of the low energy light L up significantly more, e.g., to about 98 percent, as indicated by the trace 50 in FIG. 2. Therefore, this combination of the ultra-thin, monolithic, multi-bandgap, tandem structure of the high E cell 20 with the dual purpose optical coating 40, dielectric spacer 44, and metal back surface reflector 42 is very effective to maximize absorption and conversion of the high energy light, i.e., wavelengths shorter than the cut-off wavelength λ_{g}, to electricity while maximizing reflection and minimizing losses of the low energy light L, i.e., wavelengths longer than the cut-off wavelength λ_{g}.

The modeling of the optimum subcell bandgaps for a particular spectrum or band of incident light can be done in many ways, as is understood by persons skilled in the art, including, but not limited to, the constrained bottom bandgap technique described in the co-pending U.S. patent application Ser. No. 12/121,463, entitled “Monolithic, Multi-bandgap, Tandem, Ultra-thin, Strain-counterbalances, Photovoltaic Energy Converters With Optimal Subcell Bandgaps,” whᵢch is incorporated herein by reference. Therefore, the high E cell 20 can be designed with any number of subcells with any distribution of bandgaps desired for particular cost considerations and desired conversion efficiencies for particular applications, including lattice-mismatched subcells to reach into higher and lower bandgap ranges, as described, for example, in the co-pending U.S. patent application Ser. No. 11/027,156, and co-pending U.S. patent application Ser. No. 10/515,243, both of which are incorporated herein by reference.

As mentioned above, the dielectric spacer 44 and BSR 42 can be applied as some of the last process steps of fabricating the high E cell 20. In addition to the augmentation of the reflectance of low energy light in the high E cell 20 with the dielectric spacer 44 by interrupting the Fabry-Perot interference effects associated with the BSR 42, high E cell 20 structure, and DPOC 40, as explained above, the dielectric spacer 44 also passivates the interface between the metal BSR 42 and the subcell 24, which might otherwise react with each other over time and degrade the specular interface with the BSR 42, thus the effectiveness of the metal BSR 42 to provide high quality reflectance. The dielectric spacer 42 can be applied to the subcell 24 with perforations or apertures 62, or they can be etched out, so that, when the metal BSR 42 is deposited on the cell 20, there will be enough metal contact of the BSR 42 with the back subcell 24 to serve as a back electrical contact in addition to its back surface reflector function. Therefore, a costly step of depositing another contact layer for a back surface contact can be avoided. Any suitable dielectric material, for example, SiO₂ or MgF₂, and other common dielectrics used in the electronics industry, can be used. When the high E cell 20 is placed on the receiver 12, electrical connection of the front contact 28 and BSR/back contact 42 can be made with suitable electrical leads 64, 66, as illustrated diagrammatically in FIG. 1.

As discussed above, the combination of the dual purpose optical coating 42 on the ultra-thin high E cell 20 augmented by the BSR 42 and dielectric spacer 44 results in almost all of the low energy light L of the incident solar or other radiation S being reflected to the low E cell 30. The low E cell 30 is also preferably, but not necessarily, an ultra-thin, monolithic, multi-bandgap, tandem, photovoltaic converter with a distribution of bandgaps optimized to absorb and convert the low energy light L efficiently to electricity. While three or more bandgaps in the low E cell 30 may provide better conversion efficiencies, the example low E cell 30 in FIG. 1 is illustrated for convenience with two subcells 32, 34, thus two bandgaps. Even just a single cell, i.e., one bandgap in the low E cell 30, may also be desirable or cost-effective in some applications, e.g., where high conversion efficiency is subordinate to cost considerations.

For the example split-spectrum photovoltaic converter assembly 10 illustrated in FIG. 1 with the example 1.42 eV bandgap GaAs back subcell 24 and resulting cut-off wavelength λ_{g} of 870 nm, as explained above, an appropriate two-subcell design for the low E cell 30 may comprise, for example, a front subcell of GaInAsP with a bandgap E_{g} of 0.95 eV and a back subcell of GaInAs with a bandgap E_{g} of 0.74 eV. A tunnel junction 25 for series connected subcells 32, 34 may comprise, for example, a degenerately doped GaInAsP p-n junction, or this layer 25 may be fabricated as an isolation layer if parallel subcell connections are used. A metal (e.g., gold) back surface reflector (BSR) 36 also functioning as a back electrical contact is also included. It is separated from the back subcell 34 by a dielectric spacer 37 with perforations or apertures 38 to allow electrical contact of the BSR 36 with the back subcell 34, similar to the BSR 42 and dielectric spacer 44 explained above. While not essential, the GaInAsP and GaInAs subcells 32, 34 can be grown inverted on an InP substrate with the dielectric spacer 37 and BSR/back contact 36, and then mounted on the receiver 12 or separate handle (not shown) before the parent substrate (not shown) is removed to form the ultra-thin monolithic, multi-bandgap, tandem photovoltaic converter. The grid contact 68 can then be made and the ARC 39 added similar to the method described above for the high E cell 20. An anti-reflection coating 39 for the low E cell 30 can be a conventional ARC designed to maximize transmission of the low energy light L into the subcells 32, 34 with no concern for trying to reflect any of the incidₑnt low energy light L, which is within the capabilities of persons skilled in the art.

The BSR 36 and dielectric spacer 37 are provided in the low E cell 30 tₒ reflect out any of the low energy light R that is not abₛorbed by the subcells 32, 34, e.g., light with photon energy lower than the lowest bandgap, which in the FIG. 1 example described above is the 0.74 eV bandgap of the back subcell 34. Otherwise such unabsorbed light would reach the receiver 12, where it would be absorbed and turned into heat, thereby contributing to the heat load and thermal management issues in the receiver 12. However, if it is desired to actually capture that energy as heat, for example, to use it for hot water, space heating, or for some other beneficial use of the heat, thus to form an electricity-heat cogeneration system, the BSR 36 and dielectric layer 37 may be omitted from the low E cell 30 and replaced with a transparent or absorbing back contact so that the dielectric layer 37 transmits unabsorbed light directly into the receiver 12 or the back contact. In that case, a heat transport apparatus, for example, but not limited to, the tubes 70 as shown in FIG. 1 for carrying a heat exchange fluid through the receiver 12, or other heat transfer apparatus can be provided to conduct heat away from the cells 20, 30 and out of the receiver 12. Such tubes 70 may also be used as cooling tubes for cooling the receiver 12 or for other thermal management functions.

As mentioned above, for more energy conversion efficiency, it may be desirable to use more than two low bandgap subcells in the low E cell 30. Techniques and structures for providing multiple low bandgap subcells in monolithic, tandem, photovoltaic converters, optionally including graded layers and lattice-mismatched subcells grown on InP substrates for extending subcell bandgaps into values lower than 0.74 eV, are taught in the U.S. patent application Ser. No. 10/515,243, published Jul. 27, 2006 (Publication no. 2006/0162768 A1), which is incorporated herein by reference. As also mentioned above, it may be desirable to use only one bandgap in the low E cell 30 for a less expensive system, albeit with less conversion efficiency. For example, as mentioned above, a single CuInSe₂ cell with a bandgap of about 0.69 eV is less expensive than a Group III-V cell.

The TIR optic element 46 is optional, but can be provided, as also mentioned above, to capture stray rays and direct them to the low E cell 30. Quartz, glass, or other transparent material with an index of refraction greater than air can be used for this purpose.

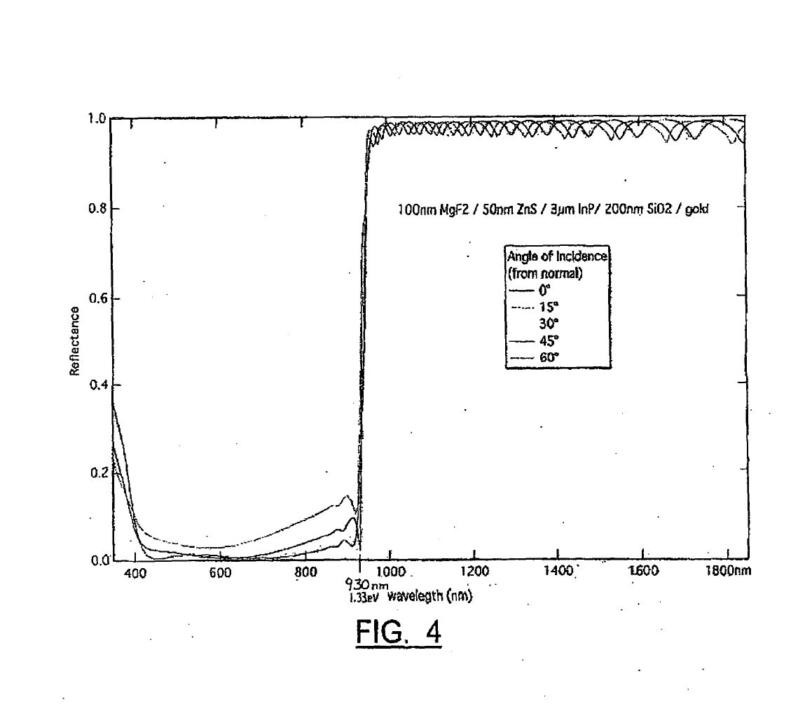

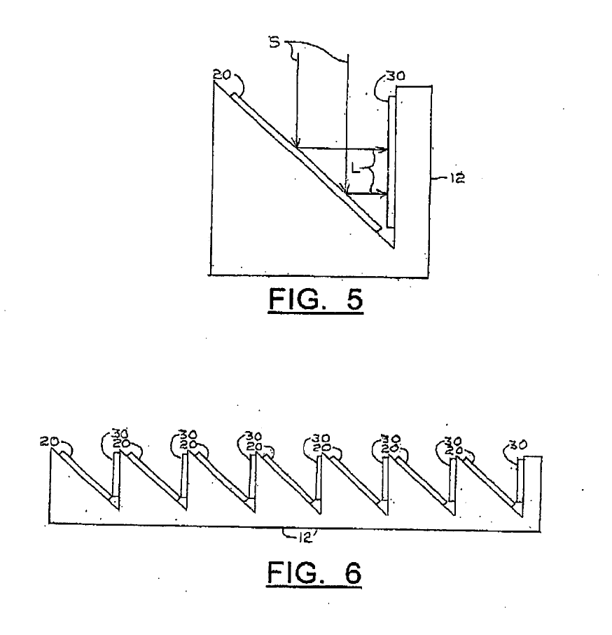

The angle of incidence of the solar radiation S on the high E cell 20 or the angle incidence of the low energy light on the low E cell 30 can be set at various angles to meet the needs of different applications as long as the angles of incidence are not set so great as to reflect incident light that should be transmitted. Modeled reflectances at different angles of incidence on an ARC comprising 100 nm MgF₂ and 50 nm ZnS layers on InP semiconductor material three μm thick with a 200 nm SiO₂ dielectric spacer and a gold BSR are shown in FIG. 4. The modeled curves for angles of incidence at zero degrees, 15 degrees, 30 degrees, 45 degrees, and 60 degrees indicate there is little difference in the transmissive and reflective effects of the ARC for angles of incidence up to 45 degrees, which leaves a significant amount of flexibility and discretion for setting. The example shown in FIG. 1 has the angle of incidence for both the incident solar radiation S on the high E cell 20 and the angle of incidence of the low energy light L on the low E cell 30 set at about 45 degrees. However, other arrangements can also be used. For example, in FIG. 5, the angle of incidence of the solar radiation S on the high E cell 20 is 45 degrees, but the angle of incidence of the low energy light L on the low E cell 30 is zero degrees, i.e., normal to the front surface of the low E cell 30.

The example assemblies shown in FIGS. 1 and 5 are suitable for solar concentrator applications. However, multiples of such assemblies appropriately scaled and strung together, for example, the extended receiver 12′ in FIG. 6 on which multiple high E cells 20 and low E cells 30 are mounted, are also conducive to flat panel (1 sun) installations. Similar extended receiver systems may also be used in concentration systems using small, high E and low E cells.

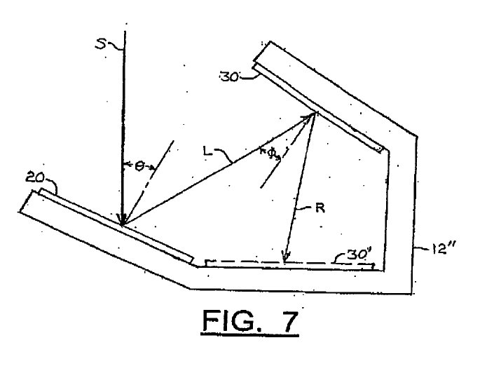

While modeling indicates that as much as a 45 degree angle of incidence is very satisfactory, as explained above, if lesser angles of incidence are desired for maximizing transmission of light by the ARCs as much as possible into the cells, the receiver can be modified to present different angles of incidence. For example, the modified receiver 12″ configuration shown in FIG. 7 presents angles of incidence θ and φ to the high E cell 20 and to the low E cell 30, respectively. This configuration also provides the option of adding a third, ultra-low energy cell 30′ for absorbing and converting even longer wavelength, lower energy light to electricity, e.g., light with photon energy less than the lowest bandgap in the low E cell 30.

While a number of example aspects and implementations have been discussed above, those of skill in the art will recognize certain modifications, permutations, additions, and subcombinations thereof. It is therefore intended that the following appended claims and claims thereafter introduced are interpreted to include all such modifications, permutations, additions, and subcombinations as are within their true spirit and scope.

The words “comprise,” ‘comprises,” “comprising,” “composed,” “composes,”, “composing,” “include,” “including,” and “includes” when used in this specification, including the claims, are intended to specify the presence of state features, integers, components, or steps, but they do not preclude the presence or addition of one or more other features, integers, components, steps, or groups thereof. Also the words “maximize” and “minimize” as used herein include increasing toward or approaching a maximum and reducing toward or approaching a minimum, respectively, even if not all the way to an absolute possible maximum or to an absolute possible minimum.

1. Photovoltaic converter apparatus for converting light comprising a spectrum of wavelengths to electric energy, comprising:
a high energy cell comprising: (i) an ultra-thin, monolithic, multi-bandgap, tandem, photovoltaic converter, including at least a front subcell with a front subcell bandgap and a back subcell with back subcell bandgap lower than the front subcell bandgap that enable said front subcell and said back subcell to absorb and convert light energy from a short wavelength band in the spectrum to electric energy, wherein a low energy edge of the short wavelength band is the longest wavelength that is absorbable and convertible to electric energy by the back subcell; and (ii) a dual purpose optical coating in front of the front subcell comprising an anti-reflection coating that transmits light in the short wavelength band and that, in combination with a back surface reflector behind the back subcell, reflects light wavelengths longer than the low energy edge of the short wavelength band; and
a low energy cell comprising an ultra-thin, monolithic, tandem, photovoltaic converter, including at least one cell with a bandgap that is lower than any bandgap in the high energy cell, said low energy cell being positioned to receive light reflected from the high energy cell.

2. The photovoltaic converter apparatus of claim 1, including a dielectric spacer positioned between the back subcell and the back surface reflector.

3. The photovoltaic converter apparatus of claim 2, wherein the back surface reflector is electrically conductive and serves as a back contact for the high energy cell.

4. The photovoltaic converter apparatus of claim 3, wherein the dielectric spacer has perforations that extend through the dielectric spacer to the back subcell and the back surface reflector/back contact has portions that extend through the perforations to make electrical contact with the back subcell.

5. The photovoltaic converter apparatus of claim 1, wherein the low energy cell includes an anti-reflection coating on the front of the low energy cell.

6. The photovoltaic converter apparatus of claim 5, including a back surface reflector on the back of the low energy cell.

7. The photovoltaic converter apparatus of claim 1, wherein the low energy cell is positioned in geometric relation to the high energy cell in a manner that incident light reflected from the high energy cell to the low energy cell has an angle of incidence on the low energy cell of not more than 45 degrees.

8. The photovoltaic converter apparatus of claim 1, including a receiver with a first platform and a second platform positioned at an angle to each other, wherein the high energy cell is mounted on the first platform and the low energy cell is mounted on the second platform at an angle to the high energy cell such that reflected low energy light from the high energy cell has an angle of incidence on the low energy cell of not more than 45 degrees.

9. The photovoltaic converter apparatus of claim 8, wherein the receiver includes electrical leads connected to the high energy cell and to the low energy cell.

10. The photovoltaic converter apparatus of claim 9, including cooling means in the receiver.

11. The photovoltaic converter apparatus of claim 10, including an electrically conductive anti-reflection coating on the back of the low energy cell to function as an electric contact for the low energy cell and to reflect light longer wavelength than the longest wavelength absorbable and convertible to electric energy by the low energy cell.

12. The photovoltaic converter apparatus of claim 10, including an electrically conductive, transparent contact on the back of the low energy cell for transmitting unabsorbed light energy into the receiver.

13. The photovoltaic converter apparatus of claim 10, including an electrically conductive contact on the back of the low energy cell that is absorptive of low energy light that is not absorbed in the low energy cell for converting the unabsorbed light to heat.

14. The photovoltaic converter apparatus of claim 10, wherein the cooling means includes heat transfer means for conducting heat away from the receiver.

15. Photovoltaic converter apparatus for converting light comprising a spectrum of wavelengths to electric energy, comprising:
a high energy cell comprising: (i) an ultra-thin, monolithic, multi-bandgap, tandem, photovoltaic converter, including at least a front subcell with a front subcell bandgap and a back subcell with back subcell bandgap lower than the front subcell bandgap that enable said front subcell and said back subcell to absorb and convert light energy from a short wavelength band in the spectrum to electric energy, wherein a low energy edge of the short wavelength band is the longest wavelength that is absorbable and convertible to electric energy by the back subcell; and (ii) means on the front of the high energy cell for minimizing reflectance of light in the short wavelength band and for coupling low energy light reflecting in the high energy cell out of the front of the high energy cell; and (iii) means behind the back subcell for reflecting light wavelengths longer than the low energy edge of the short wavelength band; and
a low energy cell comprising an ultra-thin, monolithic, tandem, photovoltaic converter, including at least one cell with a bandgap that is lower than any bandgap in the high energy cell, said low energy cell being positioned to receive light reflected from the high energy cell.

16. The photovoltaic converter apparatus of claim 15, including a means positioned between the back subcell and the back surface reflector for combining with the means on the front of the high energy cell to couple low energy light reflecting in the high energy cell out of the front surface of the high energy cell.

17. The photovoltaic converter apparatus of claim 15, wherein mean behind the back subcell is electrically conductive and serves as a back contact for the high energy cell.

18. A method of converting solar energy to electric energy, comprising:
placing a high energy cell comprising a first subcell with a first bandgap and a second subcell with a second bandgap that less than the first bandgap in a position to have the front of the high energy cell exposed to the solar energy;
minimizing reflectance of the front of the high energy cell in a high energy band that has a low energy edge defined by the longest wavelength of light that is absorbable and convertible to electric energy by the second subcell with the second bandgap by positioning a dual purpose optical coating comprising an anti-reflection coating on the front surface of the high energy cell that is tuned in combination with the first and second subcells to couple the high energy band light into the subcells where the subcells absorb the high energy band light and convert it to electric energy;
maximizing reflectance of low energy light having wavelengths longer than the longest wavelength of light that is absorbable and convertible to electric energy by the second subcell by providing a back surface reflector on the back of the subcell to reflect the low energy light transmitted by the first and second subcells back to the dual purpose optical coating and positioning a dielectric spacer between the second subcell and the back surface reflector with a thickness that is tuned to complement the dual purpose optical coating in optical interference to couple the low energy light out the front of the high energy cell;
positioning a low energy cell with at least one photovoltaic cell or subcell junction with a bandgap lower than the bandgap of the second subcell in the high energy cell in a position to have the low energy light reflected by the high energy cell incident on the low energy cell; and
absorbing and converting at least some of the low energy light reflected by the high energy cell to electric energy in the low energy cell.

19. The method of claim 18, wherein the first cell is an ultra-thin cell.

20. The method of claim 18, wherein the second cell is an ultra-thin cell.

21. The method of claim 18, including mounting the first cell and the second cell on a receiver that positions the first cell and the second cell in a geometric relation to each other such that the low energy light reflected from the high energy cell is incident on the low energy cell at an incident angle of not more than 45 degrees.

22. The method of claim 21, including reflecting light in the low energy cell that is not converted to electric energy in the low energy cell back through the front of the low energy cell.

23. The method of claim 21, including absorbing light in the low energy cell that is not converted to electric energy in the low energy cell into the receiver.
